(19) United States
(12) Patent Application Publication
(10) Pub. No.: US 2008/0305443 A1
(43) Pub. Date: Dec. 11, 2008

(54) PATTERN FORMING METHOD USING RELACS PROCESS

(76) Inventor: Hiroko NAKAMURA, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/135,548

(22) Filed: Jun. 9, 2008

(30) Foreign Application Priority Data
Jun. 11, 2007 (JP) 2007-154484

(51) Int. Cl. G03F 7/004

(52) U.S. Cl. 430/325

(57) ABSTRACT

A resist pattern is formed on a to-be-processed film. Ions are implanted in the upper surface of the resist pattern. After ion implantation, an organic film is formed to cover the resist pattern and heated. A crosslinked resin film made of the organic film which has crosslinked is formed on the sidewall of the resist pattern by developing the organic film after heating. After formation of the crosslinked resin film, the resist pattern is removed. The to-be-processed film is processed using the crosslinked resin film as a mask.

### CROSS-REFERENCE TO RELATED APPLICATIONS

This application is based upon and claims the benefit of priority from prior Japanese Patent Application No. 2007-154484, filed Jun. 11, 2007, the entire contents of which are incorporated herein by reference.

### BACKGROUND OF THE INVENTION

1. Field of the Invention

The present invention relates to a lithography technique of forming a semiconductor device pattern and, more particularly, to a pattern forming method of forming a pattern with double the frequency of a resist pattern using a RELACS process.

2. Description of the Related Art

There is a growing need for micropatterning of semiconductor devices, although the wavelength of exposure light in an exposure apparatus shortens, and the NA (Numerical Aperture) increases. To meet this requirement, pattern forming methods of doubling the frequency (or halving the pitch) have been proposed and examined. One of the methods of forming a pattern which doubles the frequency is called spacer process. RELACS (Resolution Enhancement Lithography Assisted by Chemical Shrink) is known as a method of forming a pattern on a sidewall. This technique crosslinks a resin using an acid generated upon exposure and remaining on the side surface of a resist pattern, thereby forming a pattern on the sidewall of the resist pattern (e.g., U.S. Pat. No. 6,383,952).

In a fine pattern, however, an acid is generated even on the upper surface of the pattern due to diffraction of light upon exposure. Hence, a RELACS film remains even on the upper surface of the pattern. If RIE (Reactive Ion Etching) is performed in this state to remove the resist, the resist and RELACS mix. This makes it difficult to remove the resist.

### BRIEF SUMMARY OF THE INVENTION

According to a first aspect of the present invention, there is provided a pattern forming method comprising forming a resist pattern on a to-be-processed film, implanting ions in an upper surface of the resist pattern, forming an organic film to cover the resist pattern after ion implantation, heating the organic film to crosslink, developing the organic film after heating, forming a crosslinked resin film made of the organic film on a sidewall of the resist pattern, removing the resist pattern after formation of the crosslinked resin film, and processing the to-be-processed film using the crosslinked resin film as a mask.

According to a second aspect of the present invention, there is provided A pattern forming method comprising forming a resist pattern on a to-be-processed film, selectively implanting ions in a part of an upper surface of the resist pattern, forming an organic film to cover the resist pattern after ion implantation, heating the organic film to crosslink, developing the organic film after heating, forming a crosslinked resin film made of the organic film on a sidewall of a resist pattern in the area where ions were implanted and on a sidewall and an upper surface of a resist pattern in the area where ions were not implanted, removing the resist pattern in the area where ions were implanted, and processing the to-be-processed film using the crosslinked resin film and the resist pattern in the area where ions were not implanted as a mask.

### BRIEF DESCRIPTION OF THE SEVERAL VIEWS OF THE DRAWING

FIGS. 1A to 1H are sectional views showing the steps in a conventional pattern forming method using a spacer process;

FIGS. 2A to 2F are sectional views showing the steps in a pattern forming method according to the first embodiment of the present invention;

FIG. 3 is a sectional view for explaining a state in which a RELACS pattern is formed on the upper surface of a resist pattern without ion implantation;

FIG. 4 is a sectional view for explaining a state in which an ion-implanted layer is formed in a BARC formed on a to-be-processed film in the first embodiment; and

FIGS. 5A to 5F are sectional views showing the steps in a pattern forming method according to the second embodiment of the present invention.

### DETAILED DESCRIPTION OF THE INVENTION

### First Embodiment

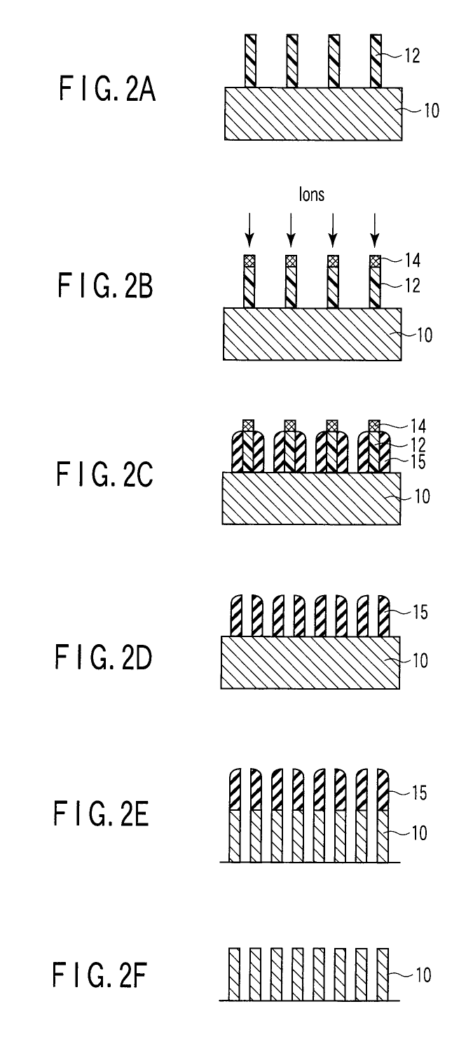

A pattern forming method according to the first embodiment of the present invention will be described with reference to FIGS. 2A to 2F.

In this embodiment, a sidewall pattern is formed using RELACS. Additionally, ions are implanted in advance to prevent a RELACS film from remaining on the upper surface of a resist pattern, thereby deactivating the acid in the resist.

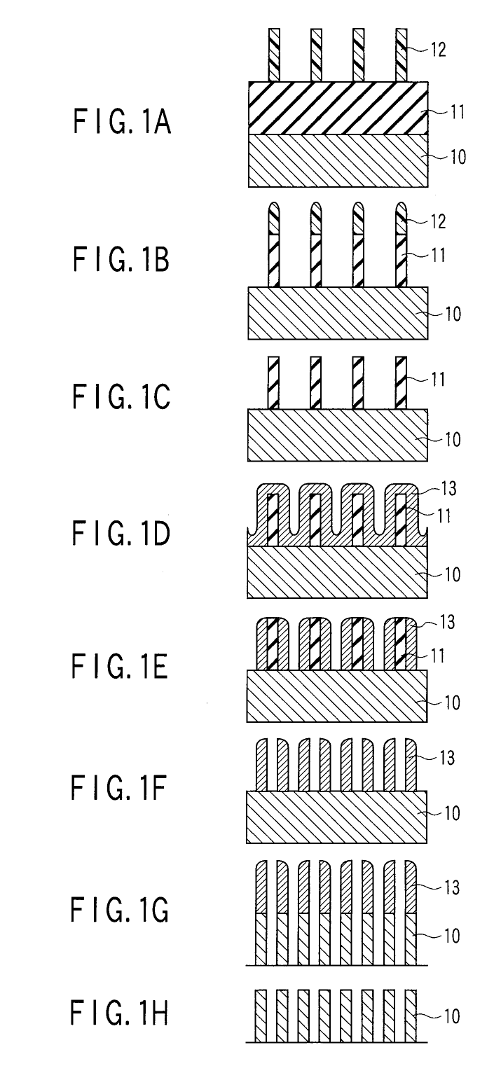

As a comparison to this embodiment, a conventional spacer process will be described first with reference to FIGS. 1A to 1H. In the conventional spacer process, as shown in FIG. 1A, an oxide film 11 such as a TEOS film is formed on a to-be-processed film 10 made of, e.g., silicon (Si), polysilicon (poly-Si), an oxide film, or tungsten (W). A resist pattern 12 is formed on the oxide film 11.

At this time, a desired resist pattern 12 may directly be formed by exposure. Alternatively, the resist pattern 12 may be formed by slimming. In this case, a resist pattern 12, of which line width is wider than the desired one, is formed and then slimmed by ashing or the like, thereby ensuring a wide process margin for the line width and pitch.

As shown in FIG. 1B, the resist pattern 12 is transferred to the oxide film 11. Then, the resist pattern 12 is peeled, as shown in FIG. 1C.

As shown in FIG. 1D, an amorphous silicon (a-Si) film is formed by sputtering to cover the upper surface and sidewall of the oxide film pattern 11 and the exposed surface of the to-be-processed film 10. As shown in FIG. 1E, an a-Si layer 13 formed on the upper surface of the oxide film pattern 11 is removed by planarization using, e.g., RIE.

As shown in FIG. 1F, the oxide film pattern 11 (TEOS film) is removed. As shown in FIG. 1G, the to-be-processed film 10 made of, e.g., an electrode material is etched using the a-Si layer 13 as a mask. This spacer process requires a number of steps and thus increases the cost.

In the first embodiment, a pattern is formed using the process shown in FIGS. 2A to 2F.

As shown in FIG. 2A, a resist pattern 12 is formed on a o-be-processed film 10 made of, e.g., silicon (Si), polysilicon (poly-Si), an oxide film, or tungsten (W), as in the RELACS process.

At this time, a desired resist pattern 12 may directly be formed by exposure. Alternatively, a resist pattern 12 may be formed by slimming. That is, a resist pattern 12, of which line width is wider than the desired one, is formed and then slimmed by ashing or the like, thereby ensuring a wide process margin for the line width and pitch. This is also the same as in the above-described comparative example.

After that, as shown in FIG. 2B, ions are implanted in only the surface of the resist pattern 12. When exposure light irradiates a chemical amplified resist, a PAG as an photoacid generator decomposes and generates an acid. In a positive-tone resist, an acidic group is generated by a deprotection reaction between the generated acid and a protected group in the resist polymer. The polymer having the acidic group dissolves in an alkaline developer so that a resist pattern is obtained. The intensity of the aerial image upon exposure does not so steeply change between the perspective resist pattern portion and the portion that dissolves in development. The acid diffuses at the time of post-exposure baking. For these reasons, the acid or acidic group exists even in the resist pattern portion. When an ion-implanted layer 14 is formed by ion implantation, the acid in the resist is deactivated.

Then, a RELACS process is performed, as shown in FIG. 2C.

A general RELACS process will be described.

A RELACS agent is an organic material containing a resin which crosslinks upon heating in the presence of an acid. Upon heating in the presence of an acid, a crosslinking reaction occurs due to the acid between crosslinkers or between a crosslinker and the acidic group such as carboxylic acid in the resist. When development is done, only the crosslinked portion remains.

When a RELACS agent (organic film) is applied on the resist pattern and heated, it thermally crosslinks with the acidic group due to the acid that exists on the sidewall and upper surface of the resist pattern. After that, development is performed using water or the like. The non-crosslinked RELACS agent portion is removed, whereas the crosslinked RELACS agent portion (RELACS film) upon thermal crosslinking remains only on the sidewall and upper surface of the resist pattern.

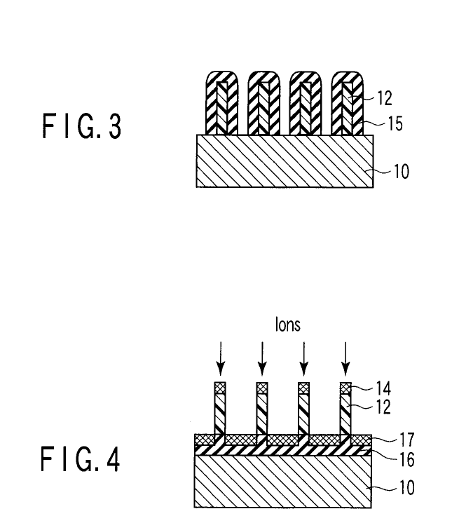

Without the ion implantation process performed in this embodiment, a RELACS film 15 remains on the upper surface of the resist pattern 12 and covers the upper surface of the resist pattern 12, as shown in FIG. 3.

In this embodiment, however, the acid on the upper surface of the resist pattern 12 is deactivated by ion implantation, as shown in FIG. 2B. After that, an organic film that is a RELACS agent is formed to cover the resist pattern 12 and heated. The RELACS process of developing the organic film is done. Then, the RELACS film 15 does not remain on the surface of the ion-implanted layer (resist pattern portion) 14 at the upper portion of the resist pattern 12, as shown in FIG. 2C.

Even in the case shown in FIG. 3, it is possible to remove the RELACS film 15 on the upper surface of the resist pattern 12 by, e.g., RIE, as shown in FIGS. 1A to 1H. However, when exposed to ions or plasma during RIE, the resist and RELACS agent readily mix. The mixing makes the resist removal difficult, although it is necessary to remove only the resist pattern 12. In the first embodiment, however, the mixing can be avoided because no RELACS agent remains on the upper surface of the resist pattern 12, as shown in FIG. 2C.

Heating is necessary for crosslinking the RELACS agent. However, the acid diffuses upon heating. If the acid diffuses to the surface, the RELACS agent crosslinks. To prevent this, the acid must be decomposed to a predetermined depth or more. It is therefore necessary to decompose and deactivate the acid to a certain depth.

On the other hand, the decomposition and deactivation of the acid must not occur too deep. Since the resist pattern portion 14 where the acid is decomposed and deactivated contains no acid, the RELACS film 15 is not formed on the sidewall. The pattern of the RELACS film 15 serves as a mask in etching the to-be-processed film 10 made of, e.g., an electrode material and need to have a sufficient film thickness to resist etching.

For these reasons, a suitable depth range of decomposition and deactivation of the acid is limited. More specifically, the depth must be larger than the acid diffusion length and smaller than a value obtained by subtracting the film thickness of the RELACS pattern required for an etching mask from the film thickness of the resist.

Acid decomposition does not occur without arrival of ions. Hence, when the resist material is determined, the ion acceleration voltage is limited. That is, to prevent the acid from reaching the surface at the time of the crosslinking reaction of the RELACS agent, a predetermined acceleration voltage or more need be ensured. On the other hand, to use the RELACS pattern as an etching mask, the ion acceleration voltage must have a predetermined value or less.

The number of arriving ions drastically decreases as the depth exceeds the projected range of the ions. Hence, to decompose and deactivate the PAG to a desired depth, the projected range of ions implanted in the resist in FIG. 2B is preferably larger than the diffusion length of the acid generated in the resist and smaller than the value obtained by subtracting the film thickness of the RELACS pattern required for an etching mask of the to-be-processed film 10 from the film thickness of the resist. The projected range of the ions is adjusted by changing the ion acceleration voltage.

The above condition is preferable because the PAG decomposition amount depends on the ion dose. For an efficient process, the above-described condition is preferable. However, the object can also be achieved by increasing the dose without satisfying the condition.

Ions to be implanted must neither affect the electrode material nor pose any problem in resist peeling. An inert gas such as He, Ar, Ne, Kr, or N₂ is preferable because it rarely poses a problem. In this embodiment, Ar is used.

After the RELACS process in FIG. 2C, the resist pattern 12 and the ion-implanted layer 14 are removed, as shown in FIG. 2D. The resist can be peeled by ashing, thinner peeling, or a method using exposure and development. In general, crosslinking occurs in the ion-implanted region. Hence, if the ion dose increases, the resist portion cannot dissolve in a thinner.

However, when the ion dose is small, the resist can be removed by thinner peeling. For this purpose, material design is done in terms of a RELACS agent and a resist which have different resistances to a thinner. A thinner which peels only the resist but not the RELACS agent is selected, thereby peeling only the resist.

If the ion dose is small, the resist can also be removed by exposure and development. In this case, a positive-tone resist is used. The resist pattern corresponds to an unexposed portion upon patterning. After the RELACS process in FIG. 2C, exposure and baking are performed. An acid generated at the exposure eliminates the protecting group of the resist so that the resist becomes soluble in a developer. After that, development is performed to remove the resist pattern 12 and the ion-implanted layer 14.

If the ion dose is large, it is necessary to peel the resist by ashing. In this case, an element which produces an oxide with a low vapor pressure upon oxidation during ashing is added to the RELACS agent. An oxide having a low vapor pressure is not eliminated during ashing so that the RELACS pattern remains even after ashing. Hence, a sidewall pattern containing the oxide is formed. A RELACS agent containing, e.g., Si is used. In this case, silicon oxide is formed as the sidewall pattern.

As shown in FIG. 2D, the resist is removed. Then, the to-be-processed film 10 is etched using the sidewall pattern (RELACS film) 15 of the RELACS agent as a mask, as shown in FIG. 2E. Finally, the RELACS film 15 is removed to obtain a desired to-be-processed film pattern 10, as shown in FIG. 2F.

Note that the pattern of the RELACS film 15 may be slimmed between the resist removal step shown in FIG. 2D and the step of processing the to-be-processed film 10 shown in FIG. 2E.

In the above explanation, the resist pattern is directly formed on the work film 10. Actually, an organic BARC (Bottom Anti-Reflective Coating) or two-layer BARC is often used to form a micropattern. The two-layer BARC is formed by combining an organic film which is a lower layer for suppressing the transmittance and a film which is an upper layer for adjusting the phase. In many cases, the latter phase adjusting layer is made of a material of a silicon oxide film base. For example, the lower transmittance adjusting layer is made of spin-on carbon, and the upper phase adjusting layer is made of spin-on glass.

If a BARC or two-layer BARC is used, it is formed on the to-be-processed film 10 shown in FIG. 2D. The steps up to FIG. 2D are the same. Then, a step of etching the BARC using the pattern of the RELACS film 15 is inserted before the step in FIG. 2E.

The BARC formed under the resist pattern improves the lithography performance because it serves as an anti-reflective coating film. In this embodiment, the BARC also provides an effect of protecting the w to-be-processed film 10 against ion implantation.

FIG. 4 is a sectional view corresponding to FIG. 2B when a BARC 16 is formed on the to-be-processed film 10. In ion implantation, ions are implanted not only in the resist but also in the BARC 16. The etching rate in BARC etching does not largely change although it slightly changes in an ion-implanted layer 17 of the BARC as compared to the non-implanted region. The BARCs 16 and 17 are peeled finally. Hence, the BARC 16 which is so thick as to prevent ions from reaching the to-be-processed film 10 can serve as the protective film of the to-be-processed film 10.

Generally, the depth of ions implanted by ion implantation almost falls within (projected range of an ion+standard deviation of the projected range×3). For this reason, when the BARC 16 is made thick more than (projected range of an ion in BARC 16+standard deviation of the projected range×3), no ions reach the to-be-processed film 10.

If the BARC 16 is a two-layer BARC, it is necessary to stop all ions in the two layers, i.e., the phase adjusting layer and the transmittance adjusting layer. In this case, it is possible to reliably stop the ions when the transmittance adjusting layer is thick more than (projected range of ions+standard deviation of range×3) in transmittance adjusting layer in terms of the ions transmitted through relatively thin phase adjusting layer on upper side.

However, if a to-be-processed film 10 which is not affected by ion implantation is used, the film thickness of the BARC 16 need not particularly be considered.

A semiconductor device manufacturing method using the pattern forming method according to the above-described embodiment will be described next. A method of forming an element isolation region and an interconnection layer including a gate electrode will be explained.

In the step of forming an element isolation region, an SiN film is formed on an Si film. Then, the SiN and Si films are etched using, as a mask, a RELACS pattern formed by the above-described method. Alternatively, a hard mask made of, e.g., an a-Si film or TEOS film may be provided between the SiN film and the RELACS pattern. After transferring the pattern to the hard mask using the RELACS pattern as a mask, the SiN and Si films may be patterned using the hard mask pattern as a mask.

In forming a NAND flash memory, a tunnel oxide film and a Poly-Si film to be used to form a floating gate may be formed before formation of the element isolation region. In this case, the SiN film is formed not on the Si film but on the Poly-Si film. Then, the films are sequentially processed up to the Si film using the RELACS pattern.

In any case, after peeling the RELACS pattern, an Si trench pattern is formed. An oxide film is formed on it and planarized by CMP. After that, the SiN film is removed. The oxide film buries the trench so that the element isolation region of an STI structure is formed.

In forming an interconnection layer including a gate electrode, a gate oxide film and a Poly-Si film are formed. Then, the Poly-Si film and gate oxide film are patterned using, as a mask, a RELACS pattern formed by the above-described method, thereby forming a gate pattern. Alternatively, for example, an SiN film may be provided between a Poly-Si film and the RELACS pattern. After patterning the SiN film using the RELACS pattern as a mask, the Poly-Si film may be patterned using the SiN film as a mask.

For a NAND flash memory, after a floating gate is formed, an interpoly insulating film is formed. A Poly-Si film serving as a control gate is formed on it. Even in this case, the RELACS pattern is formed on the Poly-Si film. An SiN film may be provided between the Poly-Si film and the RELACS pattern.

In forming an interconnection layer except the gate electrode, the lower oxide film (interlayer dielectric film) is etched using the RELACS pattern formed by the above-described method. With this process, a trench pattern made of the oxide film is formed. After that, a barrier metal and Cu seed are sputtered, and a Cu film is formed by electroplating. The Cu film on the upper surface of the oxide film is removed by CMP, thereby forming a Cu interconnection.

### Second Embodiment

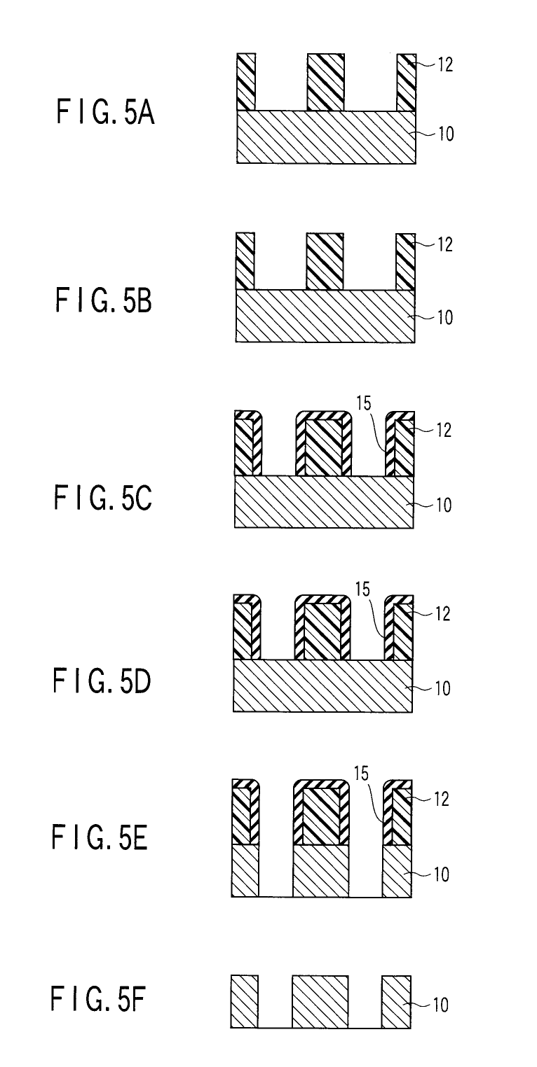

A pattern forming method according to the second embodiment of the present invention will be described with reference to FIGS. 2A to 2F and FIGS. 5A to 5F.

In the first embodiment, the explanation has been made assuming that only a cell portion is formed. However, if the cell portion and the peripheral circuit portion are formed separately, the manufacturing cost increases. In the second embodiment, a method of forming the peripheral circuit portion and the cell portion simultaneously will be described. It is therefore possible to execute the following steps of forming the peripheral circuit portion simultaneously in parallel to the steps described in the first embodiment.

FIGS. 5A to 5F are sectional views showing the steps in manufacturing a peripheral circuit portion. The steps in FIGS. 5A to 5F correspond to the steps in FIGS. 2A to 2F, respectively. The corresponding steps are executed simultaneously.

As shown in FIG. SA, in the first resist patterning step, the peripheral circuit portion is formed such that the line width becomes small, considering the change amount of the pattern dimensions in the RELACS process. If a resist slimming process such as ashing is inserted, patterning is performed in consideration of both the slimming amount and the change amount of the pattern dimensions in the RELACS process.

For the cell portion, ion implantation is executed not to form a RELACS film on the upper surface of the pattern, as shown in FIG. 2B. At this time, to selectively implant ions to only the cell portion, for example, a stencil having an opening in only an area corresponding to the cell portion is arranged above the wafer (not shown). This allows to implant ions in only the cell portion but not in the peripheral circuit portion, as shown in FIG. 5B. That is, ions are implanted in the upper surface of only a part of the whole resist pattern.

RELACS agent application, baking, and development are performed. As shown in FIGS. 2C and 5C, a RELACS film 15 is formed on the sidewall of a resist 12. In the peripheral circuit portion, however, the RELACS film 15 is also formed on the upper surface of the resist 12 because ion irradiation is not executed there (FIG. 5C). In the subsequent resist removal step shown in FIG. 5D, the resist pattern 12 in the peripheral circuit portion is not removed because the RELACS film 15 protects the resist pattern 12, unlike FIG. 2D.

As shown in FIG. 5E, in the peripheral circuit portion, a to-be-processed film 10 is etched using a pattern including the resist pattern 12 and the RELACS film 15 as a mask. At this time, in the cell portion, the to-be-processed film 10 is etched using the pattern of the RELACS film 15 as a mask, as shown in FIG. 2E.

Finally, as shown in FIG. 5F, the RELACS film 15 and the resist pattern 12 are removed, thereby obtaining a to-be-processed film 10 with a desired pattern in the peripheral circuit portion.

The above-described selective ion implantation enables to form the cell portion and the peripheral circuit portion at once.

A RELACS agent has been exemplified above. However, the present invention is not limited to the RELACS agent. Any other material is also usable if it contains a crosslinker which causes a crosslinking reaction upon heating in the presence of an acid serving as a catalyst in the resist and also crosslinks with the acidic group in the resist.

To cope with micropatterning of devices, methods of forming a pattern having a half pitch have been proposed and examined. One of the methods is a spacer process. In the conventional spacer process, a resist pattern is transferred to an oxide film, and a-Si is sputtered on its sidewall. After the a-Si layer formed on the upper surface of the oxide film pattern is removed over a whole wafer by RIE, the oxide film is removed, and an electrode material is etched using the a-Si layer sputtered on the sidewall as a mask. This process requires a number of steps and thus increases the cost.

In this embodiment, after a resist pattern is formed on a to-be-processed film, ions are implanted in only the surface of the resist to deactivate the acid on the resist pattern. After that, a process is executed using a RELACS agent made of a resin containing Si to form a crosslinked resin film only on the sidewall of the resist pattern that is not irradiated with ions, thereby forming a pattern. Then, the resist pattern is removed by, e.g., ashing, and the to-be-processed film is etched using the crosslinked resin film as a mask. This allows to form a pattern having a half pitch at a low cost while decreasing the number of steps as compared to the conventional method of transferring the resist pattern and then forming the sidewall pattern.

Since ion implantation in the upper surface of the resist pattern deactivates the acid generated from PAG in the resist, no crosslinked resin film is formed on the upper surface of the pattern. The crosslinked resin film is formed only on the sidewall of the resist. It is therefore unnecessary to remove the crosslinked resin film on the upper surface of the resist later, and mixing of the resist and the crosslinked resin can be avoided. This facilitates resist removal.

As described above, according to one aspect of this invention, it is possible to obtain a method of forming a pattern double the frequency of a resist pattern at a low cost while decreasing the number of steps.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern forming method comprising:
forming a resist pattern on a to-be-processed film;
implanting ions in an upper surface of the resist pattern;
forming an organic film to cover the resist pattern after ion implantation;
heating the organic film to crosslink;
developing the organic film after heating;
forming a crosslinked resin film made of the organic film on a sidewall of the resist pattern;
removing the resist pattern after formation of the crosslinked resin film; and
processing the to-be-processed film using the crosslinked resin film as a mask.

2. The method according to claim 1, wherein the resist pattern is formed from a chemical amplified resist, and an acid generated from an photoacid generator contained in the chemical amplified resist is deactivated by implanting the ions.

3. The method according to claim 1, further comprising slimming the resist pattern after forming the resist pattern.

4. The method according to claim 1, further comprising slimming the crosslinked resin film after forming the crosslinked resin film.

5. The method according to claim 1, wherein the ions include at least one member selected from the group consisting of He, Ne, Ar, Kr, and N₂.

6. The method according to claim 1, wherein a projected range of the ions in the resist pattern is larger than a diffusion length of an acid generated upon decomposing the photoacid generator contained in the resist pattern and smaller than a value obtained by subtracting a film thickness of the crosslinked resin film required for an etching mask of the to-be-processed film from a film thickness of the resist pattern.

7. The method according to claim 1, wherein
the crosslinked resin film contains an element which produces an oxide with a low vapor pressure, and
in removing the resist pattern, the resist pattern is removed by ashing.

8. The method according to claim 1, wherein in removing the resist pattern, the resist pattern is removed by peeling by a thinner utilizing the difference of a solvent resistance between the resist pattern and the crosslinked resin film.

9. The method according to claim 1, wherein
the resist pattern is a positive-tone resist pattern, and
in removing the resist pattern, after forming the crosslinked resin film, a region including the resist pattern is exposed and baked, and the resist pattern is removed using a developer.

10. The method according to claim 1, which further comprises an anti-reflective coating film provided between the resist pattern and the to-be-processed film, and
in which a film thickness of the anti-reflective coating film is larger than a sum of a projected range of the ions in the anti-reflective coating film and a threefold value of the a standard deviation of the projected range of the ions.

11. A pattern forming method comprising:
forming a resist pattern on a to-be-processed film;
selectively implanting ions in a part of an upper surface of the resist pattern;
forming an organic film to cover the resist pattern after ion implantation;
heating the organic film to crosslink;
developing the organic film after heating;
forming a crosslinked resin film made of the organic film on a sidewall of a resist pattern in the area where ions were implanted and on a sidewall and an upper surface of a resist pattern in the area where ions were not implanted;
removing the resist pattern in the area where ions were implanted after formation of the crosslinked resin film; and
processing the to-be-processed film using the crosslinked resin film and the resist pattern in the area where ions were not implanted as a mask.

12. The method according to claim 11, wherein the resist pattern is formed from a chemical amplified resist, and an acid generated from an photoacid generator contained in the chemical amplified resist is deactivated by implanting the ions.

13. The method according to claim 11, further comprising slimming the resist pattern after forming the resist pattern.

14. The method according to claim 11, further comprising slimming the crosslinked resin film after forming the crosslinked resin film.

15. The method according to claim 11, wherein the ions include at least one member selected from the group consisting of He, Ne, Ar, Kr, and N₂.

16. The method according to claim 11, wherein a projected range of the ions in the resist pattern is larger than a diffusion length of an acid generated upon decomposing the photoacid generator contained in the resist pattern and smaller than a value obtained by subtracting a film thickness of the crosslinked resin film required for an etching mask of the to-be-processed film from a film thickness of the resist pattern.

17. The method according to claim 11, wherein
the crosslinked resin film contains an element which produces an oxide with a low vapor pressure, and
in removing the resist pattern, the resist pattern is removed by ashing.

18. The method according to claim 11, wherein in removing the resist pattern, the resist pattern is removed by peeling by a thinner utilizing the difference of a solvent resistance between the resist pattern and the crosslinked resin film.

19. The method according to claim 11, wherein
the resist pattern is a positive-tone resist pattern, and
in removing the resist pattern, after forming the crosslinked resin film, a region including the resist pattern is exposed and baked, and the resist pattern is removed using a developer.

20. The method according to claim 11, which further comprises an anti-reflective coating film provided between the resist pattern and the to-be-processed film, and
in which a film thickness of the anti-reflective coating film is larger than a sum of a projected range of the ions in the anti-reflective coating film and a threefold value of a standard deviation of the projected range of the ions.
